(19) United States
(12) Patent Application Publication
(10) Pub. No.: US 2008/0054456 A1
(43) Pub. Date: Mar. 6, 2008

(54) SEMICONDUCTOR PACKAGE INCLUDING SILVER BUMP AND METHOD FOR FABRICATING THE SAME

(75) Inventors: Un-byoung KANG, Hwseong-si (KR); Yong-hwan KWON, Suwon-si (KR); Chung-sun LEE, Gunpo-si (KR); Woon-seong KWON, Suwon-si (KR); Hyung-sun JANG, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/828,409

(22) Filed: Jul. 26, 2007

(30) Foreign Application Priority Data
Aug. 30, 2006 (KR) 10-2006-0082923

(51) Int. Cl. H01L 23/48; H01L 21/60

(52) U.S. Cl. 257/737; 438/119; 257/E23.01; 257/E21.506

(57) ABSTRACT

A semiconductor package includes a semiconductor chip operatively attached to a conductive lead of a film circuit substrate by an indium-containing solder material and a silver-containing bump electrode, where the solder material is interposed between the conductive lead and the bump electrode.

### BACKGROUND OF THE INVENTION

1. Field of the Invention

The present disclosure relates to a semiconductor package and a method for fabricating the same and, more particularly, to a semiconductor package including a silver (Ag) bump and a method for fabricating the same.

A claim of priority is made to Korean Patent Application No. 10-2006-0082923, filed Aug. 30, 2006, in the Korean Intellectual Property Office, the disclosure of which is incorporated herein in its entirety by reference.

2. Description of the Related Art

With advances in semiconductor fabrication and packaging technology, there has been a marked increase in the production of semiconductor based devices that are highly integrated and thus smaller and lighter than older semiconductor based devices. Indeed, there has been an increase in the use of chip on film (COF) semiconductor packages and tape carrier packages (TCP) to manufacture semiconductor based devices because these packaging technologies are suited for manufacturing highly integrated semiconductor based devices.

FIG. 1 is a cross-sectional view illustrating the case where a chip using a gold (Au) bump is mounted on a film circuit substrate in a conventional semiconductor package. Referring to FIG. 1, the conventional film circuit substrate 105′ is a flexible circuit substrate used in fabricating a COF semiconductor package. The substrate 105′ typically uses an insulating film 100 made of a polyimide base. Furthermore, a conductive circuit pattern-shaped lead 110 that will form part of a predetermined circuit is formed on the insulating film 100. This circuit pattern-shaped lead 110 may be made of a metallic material such as copper (Cu) that has high electrical conductivity. Furthermore, the lead 110 is covered and protected by a protective film such as a solder resist 130. However, the portion of the lead 110 that is used to bond to the semiconductor chip 160 may not be covered by the solder resist 130. This portion is usually the inner portion of the lead that is also known as the inner lead. To this end, the inner lead is covered by a solder 120. This solder is usually tin (Sn)-plated so that chip mounting can be performed without an additional flux.

Generally, the film circuit substrate 105′ is fabricated by forming a metallic layer such as, for example, Cu, on the insulating film 100 using a deposition process such as electroplating. Furthermore, the conductive circuit pattern-shaped lead 110 is formed through an exposure process. In addition the tin (Sn) solder 120 is formed on one end of the lead 110 using electroless plating. In this case, the Sn solder 120 is usually formed to a thickness of less than 1 μm.

Typically, the semiconductor chip 160 is mounted by bonding the Au bump 140′ formed on a lower end of the semiconductor chip 160 to an inner lead of the film circuit substrate 105′. To this end, chip mounting is performed using an inner lead bonding process. Because the Sn solder 120 is formed on the inner lead, melting and bonding may be performed at a high temperature (e.g., a temperature of more than 380° C.) without a flux. In particular, during the mounting of a semiconductor chip, and, more particularly, in the state where the film circuit substrate 105 is mounted on a bonding stage (not shown) for keeping a temperature of about 100° C.-120° C., the semiconductor chip 160 is aligned and mounted on the film circuit substrate 105 using a bonding tool (not shown) that is heated to about 400° C.-500° C. At this time, the Sn solder 120 formed on the inner lead is heated to a temperature of more than 380° C. and is aligned and melted so that the entire bonding of the Au bump 140′ and the inner lead is performed. This bonding between the Au bump 140′ and the inner lead provides an electrical interconnection between the semiconductor chip 160 and the film circuit substrate 105′.

In general, gold (Au) is considerably more expensive when compared to other metals. As such, efforts for replacing an Au bump with other materials so as to reduce the price of the resulting semiconductor device are being made. For example, silver (Ag) may also be used to bond a semiconductor chip with the semiconductor substrate. Indeed, silver (Ag) does have features such as, for example, high electrical conductivity, high thermal conductivity, and good chemical stability in air, that make it an attractive replacement option.

However, there are several shortcomings associated with using Ag to bond a semiconductor chip with a semiconductor substrate. For example, if an Ag bump is applied to the semiconductor chip and a mounting process is performed using the conventional film circuit substrate, anisotropic growth of an intermetal compound generated by Ag and Sn may occur. In this case, the largest amount of an Ag₃Sn intermetal compound is generated because of a reaction between Ag and Sn. Typically, most of the Ag₃Sn intermetal compound is formed in a plate shape.

FIG. 2 is a scanning electron microscope (SEM) photo showing a spherical bump. This bump is made of solder containing a mix of Sn and Ag where the percentage of Ag in the mix is about 4%. As shown in FIG. 2, when Ag and Sn react with each other, an Ag—Sn intermetal compound Ag₃Sn is grown. Specifically, this intermetal compound grows in an anisotropic fashion. That is, the compound grows in one direction with a large thickness (generally, from several tens of micrometers to several hundreds of micrometers.)

Anisotropic growth of the Ag—Sn intermetal compound Ag₃Sn may cause various problems. For example, as illustrated in a cross-sectional view of a semiconductor package of FIG. 3, an electrical short may be formed between the leads. In particular, because the TCP or COF semiconductor package generally has a short distance (usually less than 20 μm) between leads, the probability of forming an electrical short by the Ag—Sn intermetal compound Ag₃Sn increases. Thus, there is a need to prevent the anisotropic growth of an intermetal compound generated by Ag and Sn in semiconductor packages that use an Ag bump to bond a semiconductor chip with a semiconductor substrate

### SUMMARY OF THE INVENTION

One aspect of the present disclosure includes a semiconductor package. The semiconductor package a semiconductor chip operatively attached to a conductive lead of a film circuit substrate by an indium-containing solder material and a silver-containing bump electrode, where the solder material is interposed between the conductive lead and the bump electrode.

Another aspect of the present disclosure includes a method for fabricating a semiconductor package. The method includes providing a film circuit substrate which includes a conductive lead, and operatively attaching a semiconductor chip to the conductive lead using an indium-containing solder material and a silver-containing bump electrode, where the solder material interposed between the conductive lead and the bump electrode.

Yet another aspect of the present disclosure includes a semiconductor package. The package includes a substrate including a conductive bump connecting portion, a semiconductor chip bonded to the bump connecting portion of the substrate by a silver (Ag) bump, and a metallic compound layer of Ag and indium (In) formed at a bonding surface of the substrate and the semiconductor chip.

### BRIEF DESCRIPTION OF THE DRAWINGS

The above and other features of the present disclosure will become readily apparent from the detailed description that follows, with reference to the accompanying drawings, in which:

FIG. 1 is a cross-sectional view illustrating the case where a chip using a gold (Au) bump is mounted on a film circuit substrate in a conventional semiconductor package;

FIG. 2 is a scanning electron microscope (SEM) photo showing the state where an Ag—Sn (Ag₃Sn) intermetal compound is grown in a solder bump formed of an Ag—Sn mixture;

FIG. 3 is a cross-sectional view illustrating an electrical short circuit caused by an Ag—Sn (Ag₃Sn) intermetal compound in the conventional semiconductor package;

FIG. 4 is a cross-sectional view of a semiconductor package according to an exemplary disclosed embodiment;

FIGS. 5A through 5D are cross-sectional views illustrating a method of forming an Ag bump in a semiconductor chip of the semiconductor package illustrated in FIG. 4 according to an exemplary disclosed embodiment; and

FIGS. 6A and 6B illustrate a method of fabricating a film circuit substrate in the semiconductor package illustrated in FIG. 4 according to an exemplary disclosed embodiment.

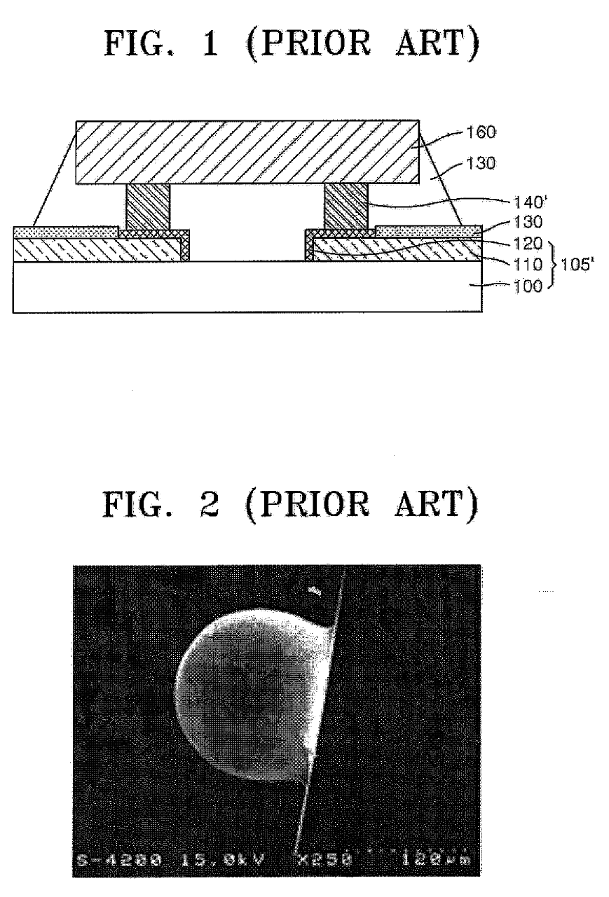

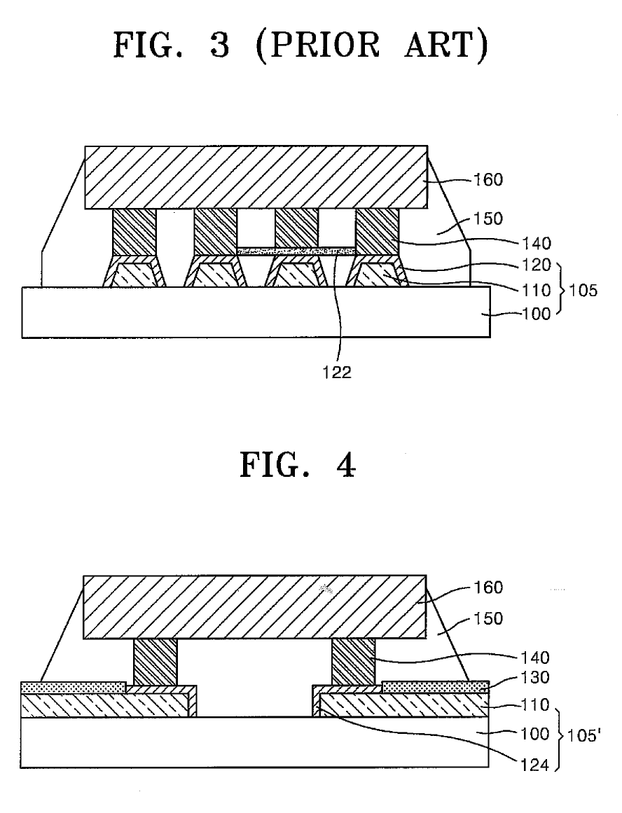

### DETAILED DESCRIPTION OF EMBODIMENTS

The present disclosure will now be described more fully with reference to the accompanying drawings, in which exemplary embodiments of the disclosure are shown. The disclosure may, however, be embodied in many different forms, and should not be construed as being limited to the embodiments set forth herein; rather, these embodiments are provided so that this disclosure will be thorough and complete, and will fully convey the concept of the invention to those skilled in the art.

FIG. 4 is a cross-sectional view of a semiconductor package according to an exemplary disclosed embodiment. Referring to FIG. 4, the semiconductor package includes a film circuit substrate 105′ having a conductive circuit pattern-shaped lead 110, a solder 124 including indium (In) formed on the lead, a silver (Ag) bump 140 bonded to the solder 124, and a semiconductor chip 160 electrically connected to the Ag bump 140. In an exemplary embodiment, the semiconductor package may be a TCP or COF semiconductor package. Furthermore, in an exemplary disclosed embodiment, the conductive circuit pattern-shaped lead 110 may be made of copper (Cu). Moreover, the lead 110 may be formed on an insulating film 100 made of polyimide. In addition, the lead 110 is covered by a protective film such as a solder resist 130 except for an inner portion (also known as an inner lead) to which the Ag bump 140 is connected. The solder 124, that includes Indium (In) is formed on the surface of the lead 110 that is not covered by the solder resist 130.

In an exemplary embodiment, the solder 124 including In may further include tin (Sn). Therefore, AgₓIn_{y} or AgₓIn_{y}Sn_{z} (x>0, y>0, z>0) which is an intermetal compound layer may be formed when the solder 124 is bonded to the Ag bump 140. Furthermore, when the solder 124 further including Sn is formed on the surface of the lead 110, the mass ratio of In may be more than 10% so as to prevent Ag—Sn anisotropic growth.

When the solder 124 including In is used on the lead 110 so as to connect the Ag bump 140 and the lead 110, anisotropic growth generated in Ag—Sn bonding may be prevented. This is because an Ag—Sn alloy has a structure in which crystal growth is easily formed in one direction and thus is easily grown in the form of a plate. On the other hand, Ag—In alloy (AgₓIn_{y}) has a different crystalline structure from that of the Ag—Sn alloy so that the Ag—In alloy (AgₓIn_{y}) is not grown in a crystalline structure in the form of a plate. In addition, the melting point of In is 157° C., which is lower than 232° C., which is a melting point of Sn so that low-temperature bonding is possible and a stress applied to the semiconductor package due to a difference in thermal expansion coefficients between the lower insulating film 100 and the upper semiconductor chip 160 can be reduced.

In an exemplary embodiment, the lead 110 may be covered by a protective film such as the solder resist 130 and may be formed to a thickness of 8-12 μm. Furthermore, the solder 124 including In may be formed to a thickness of 0.1-1 μm. In addition, the height of the Ag bump 140 bonded to the solder 124 including In may be 14-17 μm but may be changed according to the structure and use purpose of a semiconductor package.

The film circuit substrate 105′ may be a substrate applied to a TCP or COF semiconductor package, or any other type of semiconductor package. For example, a substrate applied to a different type of semiconductor package may be a rigid substrate or a flexible substrate applied to a semiconductor package for ball grid array (BGA). Alternatively, a substrate applied to a different type of semiconductor package may be a flexible substrate used in a flip-chip semiconductor package. In this case, the solder including In is a bump connecting portion to which the AG bump 140 of the semiconductor package is connected. Furthermore, a metallic compound layer AgₓIn_{y} is formed at a bonding interface between the substrate 105′ and the semiconductor chip 160. If the solder 124 of In—Sn alloy is formed on the bump connecting portion, a metal compound layer such as AgₓIn_{y}Sn_{z} (x>0, y>0, z>0) is formed on a bonding surface of the substrate 105′ and the semiconductor chip 160.

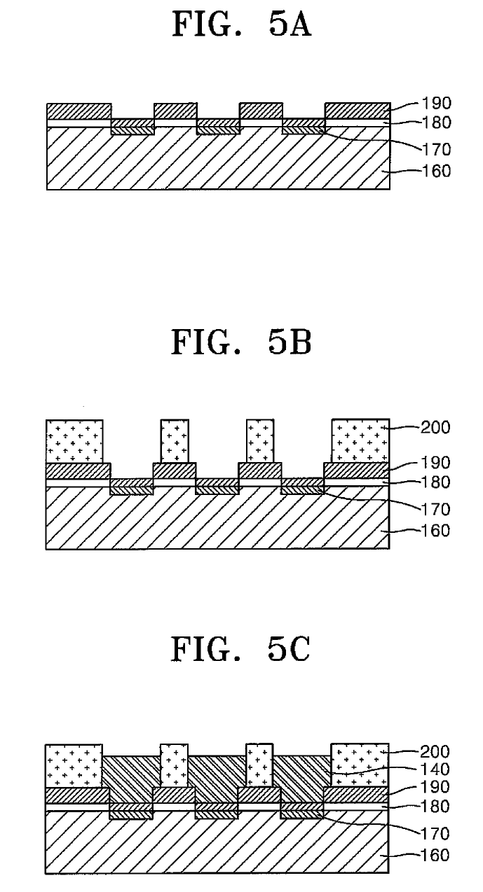

FIGS. 5A through 5D are cross-sectional views illustrating a method of forming an Ag bump in a semiconductor chip of the semiconductor package illustrated in FIG. 4. Referring to FIG. 5A, a seed metal 190 for electroplating is formed on a semiconductor chip 160 in which a chip pad 170 is formed. The seed metal 190 may be formed by depositing an adhesive layer and a wetting layer on the semiconductor chip 160. Specifically, the adhesive layer and the wetting layer may be consecutively formed in the same equipment by a process such as, for example, physical vapor deposition (PVD), chemical vapor deposition (CVD) or atomic layer deposition (ALD). In an exemplary embodiment, Titanium (Ti) or chrome (Cr) may be used for the adhesive layer and Ag, palladium (Pd), copper (Cu), nickel (Ni) may be used for the wetting layer.

Referring to FIG. 5B, after a photoresist is applied to the entire surface of the semiconductor chip 160, a photolithography process is performed and a photoresist pattern 200 is formed. The photoresist pattern 200 is formed to expose the seed metal 190 above the chip pad 170.

Referring to FIG. 5C, electroplating using the seed metal 190 is performed on the semiconductor chip 160 in which a photoresist pattern 200 is formed, thereby forming an Ag bump 140. In an exemplary embodiment, the Ag bump 140 may be formed to be slightly larger than the size of the chip pad 170.

Referring to FIG. 5D, after the photoresist pattern 200 is removed, the seed metal 190 (e.g., the wetting layer and the adhesive layer), formed under the photoresist pattern 200 is removed. To this end, the seed metal 190 under the photoresist pattern 200 may be removed using dry or wet etching using an etch selectivity of the Ag bump 140 to the seed metal 190.

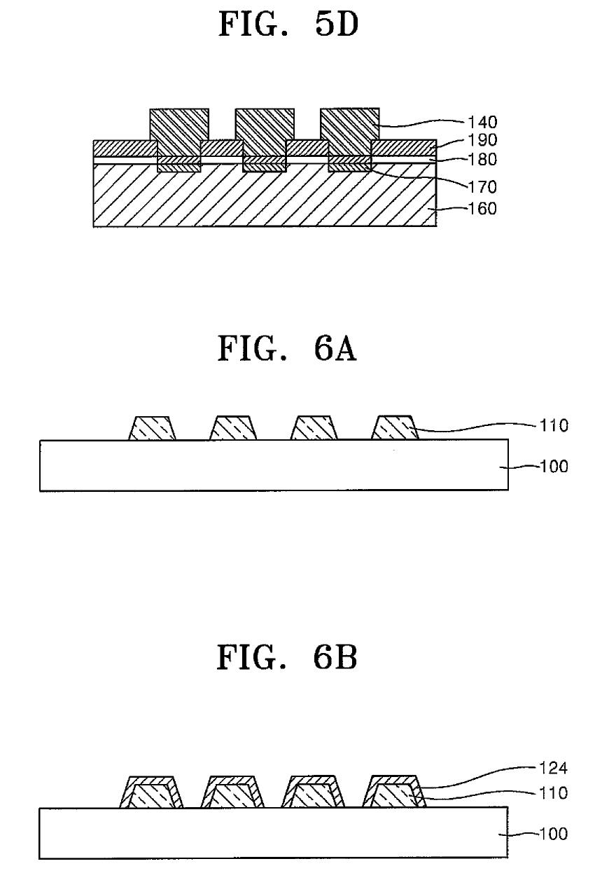

FIGS. 6A and 6B illustrate a method of fabricating a film circuit substrate in the semiconductor package illustrated in FIG. 4. Referring to FIG. 6A, a conductive circuit pattern-shaped lead 110 is formed on an insulating film 100 using any method known to one skilled in the art. For example, the lead 110 may be formed by depositing metal such as Cu on the insulating film 100 and then patterning the metal.

Referring to FIG. 6B, a solder 124 including a metal such as In or In—Sn alloy, is formed on the lead 110 to a thickness of less than 1 μm. The solder 124 including In may be formed by electroplating, non-electroplating or immersion plating.

Once the solder 124 and the Ag bump 140 are formed, the solder 124 and Ag bump 140 are bonded together so as to bond the semiconductor chip 160 to the film circuit substrate 105′. In an exemplary embodiment, the film circuit substrate 105′ is aligned on the bonding equipment (not shown). Then, the semiconductor chip 160 is aligned with the film circuit substrate 105′. Then, the semiconductor chip 160 in which the Ag bump 140 is formed, and the film circuit substrate 105′ are bonded to each other by applying heat and pressure to the solder 124 and the Ag bump 140. The heat and pressure applied to the solder 124 and Ag bump 140 cause the solder 124 including In and the Ag bump 140 to react with each other.

Because the melting point of In is lower than the melting point of Sn, the bonding process can be performed at a lower temperature than if only Sn is used. Because the bonding process is performed at a relatively lower temperature, the stress applied to the semiconductor package due to heat may be reduced. In addition, in order to improve the reliability of the bonding portion of the semiconductor chip and the film circuit substrate, a potting process of filling resin in the bonding portion may also be selectively performed.

As described above, in the disclosed semiconductor package, the Ag bump is bonded to the metallic layer on the lead using a solder that includes In such that conventional Ag—Sn anisotropic growth is prevented and reliability is improved. In addition, because the melting point of In is lower than the melting point of Sn, a bonding process of the metallic layer including Ag—In is performed at a lower temperature than one if only Sn is used. Because the bonding process is performed at a relatively lower temperature, the stress applied to the semiconductor package is reduced.

While the present disclosure has been particularly shown and described with reference to exemplary embodiments thereof, it will be understood by those of ordinary skill in the art that various changes in form and detail may be made therein without departing from the spirit and scope of the present disclosure as defined by the following claims.

What is claimed is:

1. A semiconductor package comprising a semiconductor chip operatively attached to a conductive lead of a film circuit substrate by an indium-containing solder material and a silver-containing bump electrode, the solder material interposed between the conductive lead and the bump electrode.

2. The semiconductor package of claim 1, wherein the film circuit substrate includes a polyimide-based resin.

3. The semiconductor package of claim 1, further comprising a metallic compound layer of AgₓIn_{y} (x>0, y>0) located between the bump electrode and the solder material.

4. The semiconductor package of claim 1, wherein the solder material has a thickness of 0.1 μm to 1 μm, both inclusive.

5. The semiconductor package of claim 1, wherein the semiconductor chip and the bump electrode are bonded to each other by a seed metal.

6. The semiconductor package of claim 5, wherein the seed metal includes an adhesive layer and a wetting layer.

7. The semiconductor package of claim 1, wherein the solder material further contains tin.

8. The semiconductor package of claim 7, further comprising a metallic compound layer of AgₓIn_{y}Sn_{z} (x>0, y>0, z>0) located between the bump electrode and the solder material.

9. The semiconductor package of claim 7, wherein a mass ratio of indium in the solder material is more than 10%.

10. A method for fabricating a semiconductor package, the method comprising:
providing a film circuit substrate which includes a conductive lead;
operatively attaching a semiconductor chip to the conductive lead using an indium-containing solder material and a silver-containing bump electrode, the solder material interposed between the conductive lead and the bump electrode.

11. The method of claim 10, wherein the film circuit substrate includes a polyimide-based resin.

12. The method of claim 10, further comprising forming a seed metal to attached the bump electrode to the semiconductor chip.

13. The method of claim 12, wherein the forming of the seed metal comprises:
forming an adhesive layer on the semiconductor chip; and
forming a wetting layer on the adhesive layer.

14. The method of claim 12, wherein the forming of the Ag bump comprises performing an electroplating process using the seed metal.

15. The method of claim 10, wherein the solder is formed by one of electroplating, non-electroplating, and immersion plating.

16. The method of claim 10, wherein the bonding of the solder and the Ag bump to each other comprises:
aligning the film circuit substrate on bonding equipment;
aligning the semiconductor chip on the film circuit substrate; and
applying heat and pressure to the solder and the Ag bump such that the solder and the Ag bump react with each other.

17. The method of claim 10, wherein the solder further includes tin (Sn).

18. The method of claim 10, further comprising filling an area between the semiconductor chip and the film circuit substrate with a resin.

19. A semiconductor package comprising:
a substrate including a conductive bump connecting portion;
a semiconductor chip bonded to the bump connecting portion of the substrate by a silver (Ag) bump; and
a metallic compound layer of Ag and indium (In) formed at a bonding surface of the substrate and the semiconductor chip.

20. The semiconductor package of claim 19, wherein the substrate is one of a film circuit substrate, a rigid substrate, or a flexible substrate.
